(19) United States
(12) Patent Application Publication
(10) Pub. No.: US 2018/0366630 A1
(43) Pub. Date: Dec. 20, 2018

(54) MULTILAYER THERMOELECTRIC TRANSDUCER

(71) Applicant: Murata Manufacturing Co., Ltd., Nagaokakyo-shi (JP)

(72) Inventor: Sachiko Hayashi, Nagaokakyo-shi (JP)

(21) Appl. No.: 16/111,341

(22) Filed: Aug. 24, 2018

Related U.S. Application Data
(63) Continuation of application No. PCT/JP2016/087638, filed on Dec. 16, 2016.

(30) Foreign Application Priority Data
Mar. 25, 2016 (JP) 2016-062192

(51) Int. Cl. H01L 35/22; H01L 35/32; H01L 35/02

(52) U.S. Cl. CPC H01L 35/22; H01L 35/02; H01L 35/32

(57) ABSTRACT

There is provided a multilayer thermoelectric transducer including a p-type layer containing a p-type semiconductor material, an n-type layer containing an n-type semiconductor material, and an insulating layer containing an insulating material. The p-type layer is joined to the n-type layer to constitute a pn junction pair; the p-type semiconductor material is directly joined to the n-type semiconductor material in a part of a region of the junction surface between the p-type layer and the n-type layer while, in the other region of the junction surface, the p-type semiconductor material is joined to the n-type semiconductor material with the insulating layer being interposed therebetween; the p-type semiconductor material is an alloy containing Ni; the n-type semiconductor material is a composite oxide containing Sr, Ti, Zr, a rare earth element and O with Ti and Zr satisfying a molar ratio represented by Zr/(Ti+Zr) of 0.0001≤Zr/(Ti+Zr) 0.1; and the insulating material is a partially stabilized zirconia that contains at least one metal oxide M selected from the group consisting of Y₂O₃ and CaO, and ZrO₂ with ZrO₂ and M satisfying a molar ratio represented by M/(ZrO₂+M) of 0.026≤M/(ZrO₂+M)≤0.040.

### CROSS REFERENCE TO RELATED APPLICATIONS

The present application is a continuation of International application No. PCT/JP2016/087638, filed Dec. 16, 2016, which claims priority to Japanese Patent Application No. 2016-062192, filed Mar. 25, 2016, the entire contents of each of which are incorporated herein by reference.

### TECHNICAL FIELD

The present invention relates to a multilayer thermoelectric transducer.

### BACKGROUND ART

Methods that convert thermal energy to electric energy are divided into direct methods and indirect methods. In the indirect methods, electric power is generated by transducing thermal energy into mechanical energy or the like. A representative method thereof is thermal power generation. On the other hand, thermoelectric transducers are known as transducers used in the direct methods.

Japanese Patent Application Laid-Open No. 2004-281928 (Patent Document 1) discloses a multilayer thermoelectric transducer prepared by degreasing and firing a laminate composed of a p-type semiconductor sheet (p-type layer), an n-type semiconductor sheet (n-type layer), and an insulating layer. The multilayer thermoelectric transducer has a structure including a p-type layer and an n-type layer joined directly to each other in a part of a region of the junction surface with the p-type layer being joined to the n-type layer through an insulating layer in the other region in the junction surface.

The multilayer thermoelectric transducer, as compared with π-(pi-) type thermoelectric transducers having a gap layer provided for insulation between a p-type layer and an n-type layer, can enhance a proportion of a thermoelectric transduction material in the transducer and also can enhance the strength of the transducer. Further, since the p-type layer is joined directly to the n-type layer, the multilayer thermoelectric transducer is advantageous over the π-(pi-)type thermoelectric transducer in which these layers are joined to each other with an electrode or the like provided between the layers in that the circuit resistance can be reduced. By virtue of these features, the multilayer thermoelectric transducer is advantageous in that thermoelectric transduction efficiency and the strength of the transducer can be improved (see, for example, International Publication No. 2012/011334 (Patent Document 2).

For multilayer thermoelectric transducers disclosed in Patent Documents 1 and 2, the output of actual power generation was lower than an output expected theoretically from the configuration of the p-type layer, the n-type layer, and the insulating layer. Accordingly, an improvement that realizes the development of satisfactory power generation capacity expected for the multilayer thermoelectric transducer has been desired.

The present invention has been made with a view to solving the above problem and an object of the present invention is to provide a multilayer thermoelectric transducer having a high power generation capacity.

### BRIEF SUMMARY OF THE INVENTION

The above object can be attained by a multilayer thermoelectric transducer including a multilayer thermoelectric transducer comprising:

a p-type layer containing a p-type semiconductor material, the p-type layer having a main surface;

an n-type layer containing an n-type semiconductor material, the n-type layer having a main surface, the main surfaces of the p-type and n-type layers facing one another; and

an insulating layer containing an insulating material located between a portion of main surfaces of the p-type and n-type layers such that the p-type layer directly contacts the n-type layer at a first portion of the main surfaces of the p-type and n-type layers to constitute a pn junction pair and a second portion of the main surfaces of the p-type and n-type layers are separated by the insulating layer; wherein:

the p-type semiconductor material is an alloy containing Ni;

the n-type semiconductor material is a composite oxide containing Sr, Ti, Zr, a rare earth element and O with Ti and Zr satisfying a molar ratio represented by Zr/(Ti+Zr) of 0.0001≤Zr/(Ti+Zr)≤0.1; and

the insulating material is a partially stabilized zirconia that contains at least one metal oxide M selected from a group consisting of Y₂O₃ and CaO, and ZrO₂ with ZrO₂ and M satisfying a molar ratio represented by M/(ZrO₂+M) of 0.026≤M/(ZrO₂+M)≤0.040.

The present inventors have made studies on compositions of individual layers necessary for an improvement in a power generation capacity of the multilayer thermoelectric transducer. As a result, the present inventors have found that, when (a) a composite oxide containing Ti and Zr with a molar ratio represented by Zr/(Ti+Zr) is used for the n-type semiconductor and is regulated in a predetermined range and (b) a partially stabilized zirconia with a molar ratio represented by M/(ZrO2+M) is regulated in a predetermined range, the power generation capacity is significantly improved over the power generation capacity when the two requirements are not satisfied.

The reason for the enhanced power generation capacity is believed to reside in that Zr is contained as a common element in the insulating material and the n-type semiconductor. When a common element is contained in the insulating material and the n-type semiconductor material, the junction between dissimilar materials is improved. In addition, Zr does not significantly lower semiconductor properties and can function so as for the insulating layer and the n-type layer to have the same sintering behavior, and, thus, the shrinkage of the insulating layer and the n-type layer in the sintering is high. Consequently, it is believed that the density of the multilayer thermoelectric transducer is creased, contributing to an improved power generation capacity.

In the multilayer thermoelectric transducer of the present invention, the metal oxide M contained in the insulating material is preferably Y2O3.

In the multilayer thermoelectric transducer of the present invention, the p-type semiconductor material is preferably an alloy containing Ni and Mo.

The alloy containing Ni and Mo can improve sinterability in integral sintering with the n-type layer and the insulating layer.

In the multilayer thermoelectric transducer of the present invention, preferably, the rare earth element contained in the n-type semiconductor material is La. Among trivalent rare earth elements, La is easiest to be dissolved in solid solution in SrTiO3 that is a preferred composite oxide as the n-type semiconductor material, contributing to a further lowering in resistance of the multilayer thermoelectric transducer.

In the multilayer thermoelectric transducer of the present invention, preferably, the p-type layer further contains a material usable as the n-type semiconductor.

Further, preferably, the material used as the n-type semiconductor contained in the p-type layer contains Zr.

The incorporation of the material used as the n-type semiconductor in the p-type layer is preferred because the sintering behavior of the p-type layer is likely to become close to the sintering behavior of the n-type semiconductor.

In particular, when Zr is contained in the p-type layer, all of the n-type layer, the insulating layer, and the p-type layer contain Zr, leading to similar sintering behavior among these three layers.

In the multilayer thermoelectric transducer of the present invention, preferably, the p-type layer further contains the n-type semiconductor material having the same composition as the n-type semiconductor material contained in the n-type layer.

When the p-type contains the n-type semiconductor material having the same composition as the n-type semiconductor material contained in the n-type layer, all the n-type layer, the insulating layer, and the p-type layer contain Zr, contributing to similar sintering behavior of the three layers. Further, in the incorporation of the n-type semiconductor material in the p-type layer, when the material having the same composition as the n-type semiconductor material is incorporated, the sintering behavior of the n-type layer becomes more close to the sintering behavior of the p-type layer. As a result, all the insulating layer, the n-type layer, and the p-type layer, when sintered, cause a high degree of shrinkage, and the density of the multilayer thermoelectric transducer is further increased, contributing to a further improved power generation capacity.

The present invention can provide a multilayer thermoelectric transducer having a higher power generation capacity.

### BRIEF DESCRIPTION OF THE DRAWINGS

FIG. 1 is a schematic perspective view of an example of a multilayer thermoelectric transducer according to the present invention.

FIG. 2 is a graph illustrating current-voltage characteristics and current-power generation characteristics for a multilayer thermoelectric transducer in Example 2 where a temperature difference was provided between the upper surface (30° C.) and the lower surface (20° C.) in the multilayer thermoelectric transducer.

### DETAILED DESCRIPTION OF THE INVENTION

An embodiment of the multilayer thermoelectric transducer in accordance with the present invention will be described. However, the present invention is not limited to the configuration disclosed.

[Multilayer Thermoelectric Transducer]

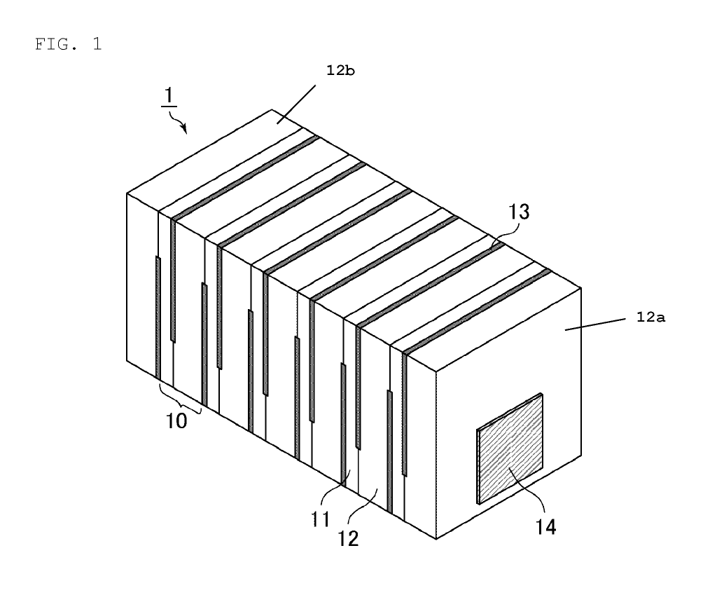

FIG. 1 is a schematic perspective view of an example of a multilayer thermoelectric transducer according to an embodiment of the present invention.

In a multilayer thermoelectric transducer 1, a plurality of p-type layers 11 containing a p-type semiconductor material and a plurality of n-type layer 12 containing an n-type semiconductor are provided. Each respective adjacent pair of p-type layers and n-type layers form a respective pn junction 10. Preferably, in the direction of the arrangement of the pn junction pairs 10 (in the longitudinal direction of the thermoelectric transducer 1), the outermost layers 12a and 12b, located at opposite ends of the thermoelectric transducer 1 are of the same conductivity type. In the embodiment of the multilayer thermoelectric transducer 1 illustrated in FIG. 1, the outermost layers 12a and 12b are n-type layers. A respective electrode 14 (only one is shown in FIG. 1) for power extraction is provided on respective exposed faces of outermost layers 12a and 12b.

Each p-type layer 11 abuts its adjacent n-type layer 12 with a respective insulating layer 13 located between part of their facing surfaces. More particularly, a first part of their facing surfaces directly abut and contact one another while a second part of their facing surfaces are separated by the intervening insulating layer 13.

Each of the n-type layers contain an n-type semiconductor material which is preferably a composite oxide containing Sr, Ti, Zr, a rare earth element (preferably La), and O. Strontium titanate (SrTiO3) with Sr site and Ti site being substituted by La and Zr may be used as the composite oxide. This composite oxide is a material represented by a compositional formula: (Sr1−xLax) (Ti1−yZry)O3 wherein x and y each are a number that is larger than 0 and is less than 1. In the compositional formula, a ratio represented by (Sr+La)/(Ti+Zr) may be any value wherein (Sr+La) represents a total molar amount of Sr and La; and (Ti+Zr) represents a total molar amount of Ti and Zr.

When an element other than La is used as the rare earth element, in the compositional formula, the La moiety is replaced by the rare earth element used.

Zr may not be present in the composite oxide in such a form that Ti site has been substituted by Zr, and Zr may be present in an externally added form.

Components other than the n-type semiconductor material may be contained in the n-type layer.

The molar ratio represented by Zr/(Ti+Zr) in the n-type semiconductor material is preferably in a range of 0.0001≤Zr/(Ti+Zr)≤0.1. This molar ratio is a ratio of the molar amount of Zr to the total molar amount of Ti and Zr. When this molar ratio requirement is satisfied, Zr (which is in both the insulating material and the n-type semiconductor material) is contained in a suitable amount in the n-type semiconductor material, contributing to an improved power generation capacity.

When the molar ratio Zr/(Ti+Zr)>0.1, amount of Zr is excessively large and the sintering of the composite oxide is suppressed, leading to lowered power generation characteristics. Further, interlayer separation is likely to occur.

In the manufacturing process of the n-type semiconductor material, PSZ (partially stabilized zirconia) may be used as grinding media. However, the amount of Zr mixed from PSZ as the grinding media into the n-type semiconductor material is very small and is negligible. Thus, in a process where PSZ is used as the grinding media without the addition of a Zr-containing compound, one skilled in the art would not use a molar ratio represented by Zr/(Ti+Zr) which is greater than or equal to 0.0001.

In the n-type semiconductor material contained in the multilayer thermoelectric transducer of the present invention, the molar ratio represented by Zr/(Ti+Zr) may be measured by ICP-AES (inductive coupling plasma emission analysis method). In ICP-AES, the n-type semiconductor material is atomized by an Ar plasma to transit the material to an excited state, and light emitted when the state is returned to the ground state is measured. The molar ratio represented by Zr/(Ti+Zr) can be determined by this measurement.

The p-type layer includes a p-type semiconductor material which is preferably an alloy containing Ni. The alloy preferably contains both Ni and Mo and may contain Cr or W instead of Mo.

Preferably, the p-type layer contains a material used as the n-type semiconductor. The p-type layer may contain, as the material used as the n-type semiconductor, a composite oxide containing Sr, Ti, Zr, a rare earth element, and O described above as the n-type semiconductor material, or alternatively may contain any material that has a composition different from the composite oxide and that is used as the n-type semiconductor material. Preferably, Zr is contained in the material used as the n-type semiconductor.

The proportion of the material used as the n-type semiconductor contained in the p-type layer is preferably 5% by weight or more, more preferably 10% by weight or more, preferably 50% by weight or less, more preferably 30% by weight or less.

Preferably, the p-type layer contains, in addition to a p-type semiconductor material, an n-type semiconductor material having the same composition as the n-type semiconductor material contained in the n-type layer. The use of the n-type semiconductor material having the same composition as the n-type semiconductor material contained in the n-type layer ensures that materials having identical sintering behavior are contained in both the n-type layer and the p-type layer. Accordingly, the sintering behavior of the n-type layer becomes closer to the sintering behavior of the p-type layer. As a result, the insulating layer, the n-type layer, and the p-type layer, when sintered, have an increased shrinkage and the density of the multilayer thermoelectric transducer is increased. This contributes to an improved power generation capacity of the multilayer thermoelectric transducer. Preferably, the material used in the n-type layer is the same as the material used in the p-type layer, because the material preparation process can be simplified.

The proportion of the n-type semiconductor material that is contained in the p-type layer and has the same composition as the n-type semiconductor material contained in the n-type layer is preferably 5% by weight or more, more preferably 10% by weight or more, preferably 50% by weight or less, more preferably 30% by weight or less.

The insulating layers 13 contain an insulating material and preferably includes a partially stabilized zirconia that contains at least one metal oxide M selected from the group consisting of Y2O3 and CaO and ZrO2. The metal oxide is not limited to one or more of the foregoing metal oxides and, for example, MgO and CeO2 can also be used.

In the insulating material, the molar ratio represented by M/(ZrO2+M) is preferably in a range of 0.026≤M/(ZrO2+M)≤0.040. This molar ratio is a ratio of the molar amount of the metal oxide M to the total molar amount of ZrO2 and the metal oxide M. When this molar ratio requirement is satisfied, Zr, that is an element common to both the insulating material and the n-type semiconductor material, is contained in a suitable amount in the n-type semiconductor material, contributing to an improved power generation capacity.

In the multilayer thermoelectric transducer of the present invention, the molar ratio represented by M/(ZrO230 M) may be measured by ICP-AES (inductive coupling plasma emission analysis method).

The metal oxide M is preferably Y2O3. In this case, the molar ratio represented by Y2O3/(ZrO2+Y2O3) satisfies 0.026≤Y2O3/(ZrO2+Y2O3≤0.040. The molar ratio is the ratio of the molar amount of Y2O3 to the total molar amount of ZrO2 and Y2O3.

Other additive elements may be contained in the insulating layer. For example, Mn, Mg, Al, Si, Ni, Cu, Fe, and V, and other elements may also be used as long as conditions necessary for integral sintering are satisfied.

[Method for Manufacturing Multilayer Thermoelectric Transducer]

An example of the method for manufacturing a multilayer thermoelectric transducer of the present invention will now be described.

The method for manufacturing a multilayer thermoelectric transducer of the present invention can be obtained by providing a p-type semiconductor material, an n-type semiconductor material, and an insulating material, laminating each material to provide a configuration of the multilayer thermoelectric transducer to prepare a laminate and firing the laminate.

An example of a method which can be used to manufacture the multilayer thermoelectric transducer of the present invention will be described.

For the p-type semiconductor material, Ni powder and Mo powder or other metal powders are provided as the p-type semiconductor material and are weighed.

For the material of the n-type semiconductor material, materials that, when sintered, are converted to a composite oxide containing Sr, Ti, Zr, a rare earth element, and O are provided and weighed.

Examples of such materials include oxides, carbonates, hydroxides, alkoxides, nitrates, chlorides, sulfates, and acetates containing Sr, Ti, Zr, or rare earth elements. Among them, powders containing Sr compounds such as SrCO3, Ti compounds such as TiO2, Zr compounds such as ZrO2, and compounds of rare earth elements (for example, La2O3) are suitable.

The particle diameter of metal powders as the p-type semiconductor material and powders as the n-type semiconductor material are not particularly limited. Preferably, however, the particle diameter is one suitable for homogeneous mixing in a later step.

Powders of materials for the n-type semiconductor material are mixed together and a solvent and grinding media are added. Thereafter they are mixed in a ball mill to obtain slurry. The slurry is dried, and the dried product is calcined in an atmospheric air to obtain an n-type semiconductor material. It is preferable to use water as the solvent and pure water is more preferred. Zirconia balls are preferred as the grinding media. The calcination temperature is preferably 1000° C. to 1400° C. A calcination temperature of 1000° C. or higher is preferred because a reaction that produces a target composite oxide can easily proceed.

The thus obtained n-type semiconductor material is further mixed and ground in a ball mill and a solvent and a binder or the like are added to the powder. Thereafter they are mixed further to obtain a slurry.

Conditions for mixing and grinding are not particularly limited as far as grinding conditions can provide powders that, in sintering after lamination, allows the n-type semiconductor material to be sintered well.

The slurry thus prepared is formed into a sheet by sheet forming methods such as doctor blading and comma coating to prepare an n-type material sheet for n-type layer formation.

Preferred solvents for slurry preparation include Ekinen (tradename: a mixed solvent composed mainly of ethanol) and toluene. Zirconia balls are preferred as the grinding media.

P-type semiconductor materials are mixed together and grinding media are added. These components are then mixed in a ball mill to obtain a powder. A solvent and a binder or the like are added to the powder and the mixture is further mixed to obtain a slurry. The slurry is formed into a sheet by sheet forming methods such as doctor blading or comma coating to prepare a p-type material sheet for p-type layer formation.

When an n-type semiconductor material is incorporated in the p-type layer, the n-type semiconductor material obtained after calcination in the above step may be mixed into the p-type semiconductor material when mixing in a ball mill.

Alternatively, any material used as the n-type semiconductor, which is different from the n-type semiconductor material obtained in the above step, may be mixed into the p-type semiconductor material. Preferably, the solvents and grinding media used for slurry preparation are the same as those used for the preparation of the slurry for n-type material sheet formation.

A powder of partially stabilized zirconia containing at least one metal oxide selected from the group consisting of Y2O3 and CaO, and ZrO2 is provided as the insulating material. Preferably, a Y2O3-ZrO2 powder that has been prepared so as to satisfy a molar ratio represented by Y2O3/(ZrO2+Y2O3) of 0.026≤Y2O3/(ZrO2+Y2O3)≤0.040 is provided and weighed. The molar ratio is a ratio of the molar amount of Y2O3 to the total molar amount of ZrO2 and Y2O3.

Varnish and a solvent are mixed into the partially stabilized zirconia powder and the mixture is kneaded in a mill to obtain an insulating paste.

The insulating paste is printed on respective positions of the n-type material sheet and the p-type material sheet. The printing positions are selected such that, when the n-type material sheet and the p-type material sheet are alternately laminated, the n-type material sheet and the p-type material sheet are in direct contact with each other in a part of a region of joint (abutting) surfaces of the n-type and p-type material sheets while, in another region, an insulating paste is disposed between the adjacent n-type and p-type material sheets.

The n-type material sheet with the insulating paste printed thereon and the p-type material sheet with the insulating paste printed thereon are laminated to prepare a laminate. If desired, n-type and p-type material sheets that do not have an insulating paste printed thereon may be used in addition to the n-type and p-type material sheets that do have an insulating paste printed thereon. For example, a p-type material sheet with the insulating paste printed thereon, an n-type material sheet with the insulating paste printed thereon, an n-type material sheet with the insulating paste not printed thereon, and a p-type material sheet with the insulating paste printed thereon, etc., may be laminated in that order.

The thickness of each of the p-type layers or n-type layers in the multilayer thermoelectric transducer may be regulated by using the n-type material sheet with the insulating paste not printed thereon or the p-type material sheet with an insulating paste not printed thereon.

Preferably, the thickness of each layer in the laminate and the number of laminated layers (number of pn junction pairs) is determined by taking into consideration the desired electromotive force and current obtained by the multilayer thermoelectric transducer and the resistance of load used.

The laminate thus prepared is subjected to pressure bonding and molding to prepare a molded product and the molded product is cut with a dicing saw or the like into a predetermined size. If necessary, an electroconductive paste may be printed at opposite ends of the molded product to form respective electrodes. When the p-type layer is disposed at opposite ends of the molded product, the p-type layer provided at the opposite ends may be used as the electrode without providing an electroconductive paste.

The cut molded product is degreased and fired to obtain a fired product.

The laminate may be contact-bonded by any method without particular limitation. An isotropic hydrostatic pressing (CIP) method, however, is preferred. Firing methods usable herein include hot pressing, SPS sintering (discharge plasma sintering), and HIP (hot isotropic pressing). The firing temperature is preferably 1200° C. to 1400° C. The firing is preferably carried out in an atmosphere that does not oxidize the Ni-containing alloy which is the p-type semiconductor material, preferably in a low-oxygen atmosphere. The partial pressure of oxygen in the low-oxygen atmosphere is preferably 10-15 MPa to 10-10 MPa.

Further, it is preferable that the fired product is polished.

The multilayer thermoelectric transducer of the present invention may be used in applications such as power sources for wireless communication.

### EXAMPLES

The multilayer thermoelectric transducer of the present invention will be disclosed in more detail by the following Examples.

The present invention, however, is not limited to these Examples only.

[Preparation of Multilayer Thermoelectric Transducer

### Example 1

A metallic Ni powder and a metallic Mo powder were used as starting materials of a p-type semiconductor material, and La2O3, SrCO3, TiO2, and ZrO2 were used as starting materials of an n-type semiconductor material. These starting materials were weighed to provide compositions specified in Table 1.

For the n-type semiconductor material, pure as a solvent and PSZ as grinding media were added to the starting materials of the n-type semiconductor materials, followed by mixing in a ball mill. The slurry thus obtained was dried and the dried product was calcined in an atmospheric air at a temperature of 1000° C. to 1400° C. to obtain an n-type semiconductor material powder.

Toluene, Ekinen, binder and the like were added to the n-type semiconductor material powder. The mixture was mixed further, and the slurry thus obtained formed with a comma coater into a sheet to obtain an n-type material sheet.

For the p-type semiconductor material, the starting materials of the p-type semiconductor material and the calcined n-type semiconductor material obtained in the above step were mixed together and the mixture was subject to grinding in a ball mill for 5 hr. Toluene, Ekinen, binder and the like were added to the powder, the mixture was further mixed, and the slurry thus obtained was formed with a comma coater into a sheet to obtain a p-type material sheet containing the n-type semiconductor material and the p-type semiconductor material. The proportion of the n-type semiconductor material and p-type semiconductor material is shown in Table 1.

A Y2O3-ZrO2 powder was weighed as an insulating material. The Y2O3-ZrO2 powder used was described in Table 1. Varnish and a solvent were mixed into the Y2O3-ZrO2 powder, and an insulating paste was prepared in a roll mill.

The insulating paste thus prepared was printed on each of the n-type material sheet and the p-type material sheet to a thickness of 5 μm. The 50 μm-thick p-type material sheet with the insulating paste printed thereon, the 50 μm-thick n-type material sheet with the insulating paste printed thereon and the 150 μm-thick n-type material sheet with the insulating paste not printed thereon were laminated in that order to prepare a laminate including 50 pn junction pairs, each junction pair consisting of the three sheets.

Further, the 50 μm-thick n-type material sheet with the insulating paste printed thereon and the 150 μm-thick n-type material sheet with the insulating paste not printed thereon was added on an outer side of the p-type material sheet located at the end to prepare a laminate with the n-type material sheet provided at opposite ends.

The laminate thus prepared was contact-bonded by isotropic hydrostatic pressing to obtain a molded product.

Subsequently, the molded product was cut into a predetermined size with a dicing saw. The dimension (length, width, and thickness) of the cut molded product was measured and recorded as the dimension of the transducer before firing. An electroconductive paste was printed at both ends of the molded product. The molded product was degreased in an atmospheric air. Thereafter, the degreased molded product was fired in a reducing atmosphere having an oxygen partial pressure of 10-15 MPa to 10-10 MPa at a temperature of 1200° C. to 1400° C. to obtain a fired product. The fired product was polished to prepare a multilayer thermoelectric transducer.

### Examples 2 to 16 and Comparative Examples 1 to 18

A multilayer thermoelectric transducer was prepared in the same manner as in Example 1, except that compositions of the n-type semiconductor material and the insulating material were changed as specified in Table 1.

For the Examples and the Comparative Examples, an n-type semiconductor material as used as the n-type semiconductor material in the Examples and the Comparative Examples was mixed into the p-type semiconductor material for p-type material sheet preparation.

Further, the dimension of the transducers before firing was recorded.

### Example 17

A multilayer thermoelectric transducer was prepared in the same manner as in Example 3, except that the insulating material was changed to CaO—ZrO2. Further, the dimension of the transducers before firing was recorded. The composition is shown in Table 2.

TABLE 1
p-Type semiconductor material
Ni_{0.9}Mo_{0.1} 80 wt % + n-type semiconductor material 20 wt %

| | n-Type semiconductor | | Insulating material |
|---|---|---|---|
| | material | | (Y₂O₃—ZrO₂) |
| | ComposiTin | Zr/(Ti + Zr) | Y₂O₃/(Y₂O₃ + ZrO₂) |
| Comparative Example 1 | (Sr_{0.965}La_{0.035})Ti₃ | 0 | 0.020 |
| Comparative Example 2 | (Sr_{0.965}La_{0.035})Ti₃ | 0 | 0.026 |
| Comparative Example 3 | (Sr_{0.966}La_{0.035})Ti₃ | 0 | 0.030 |
| Comparative Example 4 | (Sr_{0.966}La_{0.035})Ti₃ | 0 | 0.040 |
| Comparative Example 5 | (Sr_{0.965}La_{0.035})Ti₃ | 0 | 0.050 |
| Comparative Example 6 | (Sr_{0.965}La_{0.035})(Ti_{0.9999}Zr_{0.0001})O₃ | 0.0001 | 0.020 |
| Example 1 | (Sr_{0.965}La_{0.035})(Ti_{0.9999}Zr_{0.0001})O₃ | 0.0001 | 0.026 |
| Example 2 | (Sr_{0.965}La_{0.035})(Ti_{0.9999}Zr_{0.0001})O₃ | 0.0001 | 0.030 |
| Example 3 | (Sr_{0.965}La_{0.035})(Ti_{0.9999}Zr_{0.0001})O₃ | 0.0001 | 0.040 |
| Comparative Example 7 | (Sr_{0.965}La_{0.035})(Ti_{0.9999}Zr_{0.0001})O₃ | 0.0001 | 0.050 |
| Comparative Example 8 | (Sr_{0.965}La_{0.035})(Ti_{0.999}Zr_{0.001})O₃ | 0.001 | 0.020 |
| Example 4 | (Sr_{0.965}La_{0.035})(Ti_{0.999}Zr_{0.001})O₃ | 0.001 | 0.026 |
| Example 5 | (Sr_{0.965}La_{0.036})(Ti_{0.999}Zr_{0.001})O₃ | 0.001 | 0.030 |
| Example 6 | (Sr_{0.966}La_{0.036})(Ti_{0.999}Zr_{0.001})O₃ | 0.001 | 0.040 |
| Comparative Example 9 | (Sr_{0.966}La_{0.036})(Ti_{0.999}Zr_{0.001})O₃ | 0.001 | 0.050 |
| Comparative Example 10 | (Sr_{0.966}La_{0.035})(Ti_{0.99}Zr_{0.01})O₃ | 0.01 | 0.020 |
| Example 7 | (Sr_{0.966}La_{0.036})(Ti_{0.99}Zr_{0.01})O₃ | 0.01 | 0.026 |
| Example 8 | (Sr_{0.965}La_{0.035})(Ti_{0.99}Zr_{0.01})O₃ | 0.01 | 0.030 |
| Example 9 | (Sr_{0.965}La_{0.036})(Ti_{0.99}Zr_{0.01})O₃ | 0.01 | 0.040 |
| Comparative Example 11 | (Sr_{0.965}La_{0.035})(Ti_{0.99}Zr_{0.01})O₃ | 0.01 | 0.050 |
| Comparative Example 12 | (Sr_{0.965}La_{0.035})(Ti_{0.90}Zr_{0.10})O₃ | 0.1 | 0.020 |
| Example 10 | (Sr_{0.966}La_{0.036})(Ti_{0.90}Zr_{0.10})O₃ | 0.1 | 0.026 |
| Example 11 | (Sr_{0.966}La_{0.035})(Ti_{0.90}Zr_{0.10})O₃ | 0.1 | 0.030 |
| Example 12 | (Sr_{0.965}La_{0.035})(Ti_{0.90}Zr_{0.10})O₃ | 0.1 | 0.040 |
| Comparative Example 13 | (Sr_{0.965}La_{0.035})(Ti_{0.90}Zr_{0.10})O₃ | 0.1 | 0.050 |
| Comparative Example 14 | (Sr_{0.966}La_{0.035})(Ti_{0.80}Zr_{0.20})O₃ | 0.2 | 0.020 |
| Comparative Example 15 | (Sr_{0.966}La_{0.035})(Ti_{0.80}Zr_{0.20})O₃ | 0.2 | 0.026 |
| Comparative Example 16 | (Sr_{0.965}La_{0.035})(Ti_{0.80}Zr_{0.20})O₃ | 0.2 | 0.030 |
| Comparative Example 17 | (Sr_{0.965}La_{0.035})(Ti_{0.80}Zr_{0.20})O₃ | 0.2 | 0.040 |
| Comparative Example 18 | (Sr_{0.965}La_{0.035})(Ti_{0.80}Zr_{0.20})O₃ | 0.2 | 0.050 |
| Example 13 | (Sr_{0.975}La_{0.025})(Ti_{0.9999}Zr_{0.0001})O₃ | 0.0001 | 0.030 |
| Example 14 | (Sr_{0.955}La_{0.045})(Ti_{0.9999}Zr_{0.0001})O₃ | 0.0001 | 0.030 |
| Example 15 | (Sr_{0.966}La_{0.035})(Ti_{1.000}Zr_{0.005})O₃ | 0.005 | 0.030 |
| Example 16 | (Sr_{0.966}La_{0.036})(Ti_{0.990}Zr_{0.006})O₃ | 0.005 | 0.030 |

TABLE 2
p-Type semiconductor material
Ni_{0.9}Mo_{0.1} 80 wt % + n-type semiconductor material 20 wt %

| | n-Type semiconductor material | | Insulating material |
|---|---|---|---|
| | | Zr/ | (CaO—ZrO₂) |
| | ComposiTin | (Ti + Zr) | CaO/(CaO + ZrO₂) |
| Example | (Sr_{0.965}La_{0.035})Ti_{0.9999}Zr_{0.0001})O₃ | 0.0001 | 0.040 |
| 17 | | | |

[Calculation of Shrinkage]

For the multilayer thermoelectric transducers manufactured in the Examples and the Comparative Examples, the dimension (length, width, and thickness) of the transducers after firing was measured. The dimension of the transducers after firing was the dimension of the dimension of the transducers before electrode formation.

“Shrinkage (%)=100−(dimension of transducer after firing/dimension of transducer before firing)×100” was calculated for each of length, width, and thickness to calculate a shrinkage in each direction. The shrinkage values in the three directions were averaged to determine the shrinkage of the transducer. The shrinkages of the transducers are shown in Table 3.

[Measurement of Power Generation Characteristics]

For the multilayer thermoelectric transducers manufactured in the Examples and the Comparative Examples, the temperature of the lower end (lower temperature side) was regulated with a Peltier device to 20° C. (preset temperature of Peltier device), and the temperature of the upper end (higher temperature side) was regulated with a heater to 30° C. (preset temperature of heater).

Current was varied with a current generator, and the voltage of the transducer was measured to determine a value that provided a maximum output. Power generation characteristics for the experiment where a temperature difference was provided between the upper surface (30° C.) and the lower surface (20° C.) of the multilayer thermoelectric transducer are shown in Table 3.

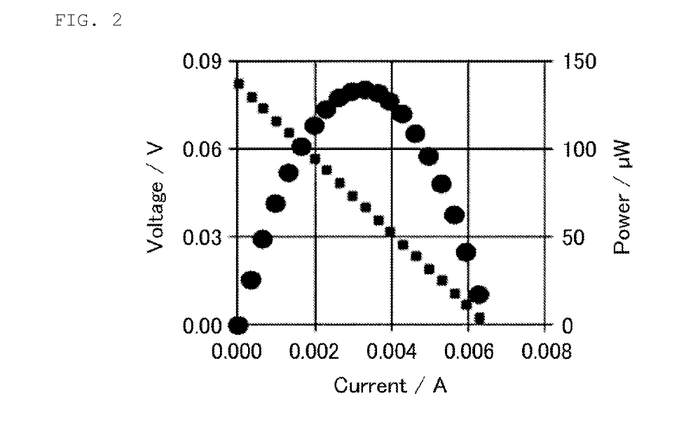

For the multilayer thermoelectric transducer of Example 2, current-voltage characteristics and current-power generation characteristics for the experiment where a temperature difference was provided between the upper surface (30° C.) and the lower surface (20° C.) of the multilayer thermoelectric transducer are shown in FIG. 2. In FIG. 2, current-power generation characteristics are shown as an upper convex curved line, and the electric power (μW) at the summit of the curve was regarded as electric power generation that provided a maximum output. Further, separation was visually inspected.

TABLE 3

| | | Electric power generaTin: |
|---|---|---|
| | Shrinkage | upper surface 30° C./lower |
| | (%) | surface 20° C. (μW) |
| Comparative Example 1 | 14.2 | 10 |
| Comparative Example 2 | 17.4 | 65 |
| Comparative Example 3 | 17.5 | 72 |
| Comparative Example 4 | 17.1 | 59 |
| Comparative Example 5 | 14.9 | 14 |
| Comparative Example 6 | 15.4 | 25 |
| Example 1 | 18.5 | 133 |
| Example 2 | 18.9 | 137 |
| Example 3 | 18.0 | 115 |
| Comparative Example 7 | 16.7 | 31 |
| Comparative Example 8 | 15.6 | 21 |
| Example 4 | 18.3 | 120 |
| Example 5 | 18.4 | 126 |
| Example 6 | 17.9 | 115 |
| Comparative Example 9 | 15.2 | 18 |
| Comparative Example 10 | 14.2 | 11 |
| Example 7 | 17.7 | 107 |
| Example 8 | 18.1 | 118 |
| Example 9 | 18.0 | 111 |
| Comparative Example 11 | — | Unmeasurable due to separaTin |
| Comparative Example 12 | 13.8 | 9 |
| Example 10 | 17.9 | 101 |
| Example 11 | 18.0 | 103 |
| Example 12 | 17.8 | 100 |
| Comparative Example 13 | — | Unmeasurable due to separaTin |
| Comparative Example 14 | — | Unmeasurable due to separaTin |
| Comparative Example 15 | 14.3 | 15 |
| Comparative Example 16 | 14.8 | 19 |
| Comparative Example 17 | 14.1 | 12 |
| Comparative Example 18 | — | Unmeasurable due to separaTin |
| Example 13 | 17.9 | 107 |
| Example 14 | 17.9 | 113 |
| Example 15 | 18.6 | 130 |
| Example 16 | 18.7 | 135 |
| Example 17 | 17.8 | 101 |

As shown in Tables 1 to 3, the multilayer thermoelectric transducers satisfying the requirements of the present invention, that is, the multilayer thermoelectric transducers wherein the n-type semiconductor material was a composite oxide containing Zr at a predetermined molar ratio and the insulating material was partially stabilized zirconia containing ZrO₂ and metal oxide at predetermined molar ratios, had a power generation of 100 μW or higher, that is, had a high power generation capacity. By contrast, the multilayer thermoelectric transducers not satisfying requirements of the present invention had a significantly lowered power generation capacity.

For the shrinkage, the multilayer thermoelectric transducers of the Examples satisfying the requirements of the present invention had a high shrinkage, whereas the multilayer thermoelectric transducers of the Comparative Examples not satisfying requirements of the present invention had a low shrinkage. For some Comparative Examples, separation was noticed, demonstrating that satisfactory shrinking could not be produced in the firing step.

Thus, the multilayer thermoelectric transducers of the Examples satisfying the requirements of the present invention had a high power generation capacity, and the reason for the high power generation capacity was believed to reside in that the shrinkage in the firing step was high, contributing to a high density of the multilayer thermoelectric transducer.

### DESCRIPTION OF REFERENCE SYMBOLS

1: multilayer thermoelectric transducer

10: pn junction pair

11: p-type layer

12: n-type layer

13: insulating layer

14: electrode

1. A multilayer thermoelectric transducer comprising:
a p-type layer containing a p-type semiconductor material, the p-type layer having a main surface;
an n-type layer containing an n-type semiconductor material, the n-type layer having a main surface, the main surfaces of the p-type and n-type layers facing one another; and
an insulating layer containing an insulating material located between a portion of main surfaces of the p-type and n-type layers such that the p-type layer directly contacts the n-type layer at a first portion of the main surfaces of the p-type and n-type layers to constitute a pn junction pair and a second portion of the main surfaces of the p-type and n-type layers are separated by the insulating layer; wherein:
the p-type semiconductor material is an alloy containing Ni;
the n-type semiconductor material is a composite oxide containing Sr, Ti, Zr, a rare earth element and O with Ti and Zr satisfying a molar ratio represented by Zr/(Ti+Zr) of 0.0001≤Zr/(Ti+Zr)≤0.1; and
the insulating material is a partially stabilized zirconia that contains at least one metal oxide M selected from a group consisting of Y₂O₃ and CaO, and ZrO₂ with ZrO₂ and M satisfying a molar ratio represented by M/(ZrO₂+M) of 0.026≤M/(ZrO₂+M)≤0.040.

2. The multilayer thermoelectric transducer according to claim 1, wherein the metal oxide M contained in the insulating material is Y₂O₃.

3. The multilayer thermoelectric transducer according to claim 1, wherein the p-type semiconductor material is an alloy containing Ni and Mo.

4. The multilayer thermoelectric transducer according to claim 3, wherein the rare earth element contained in the n-type semiconductor material is La.

5. The multilayer thermoelectric transducer according to claim 2, wherein the rare earth element contained in the n-type semiconductor material is La.

6. The multilayer thermoelectric transducer according to claim 1, wherein the rare earth element contained in the n-type semiconductor material is La.

7. The multilayer thermoelectric transducer according to claim 4, wherein the p-type layer further contains a material used as an n-type semiconductor.

8. The multilayer thermoelectric transducer according to claim 3, wherein the p-type layer further contains a material used as an n-type semiconductor.

9. The multilayer thermoelectric transducer according to claim 2, wherein the p-type layer further contains a material used as an n-type semiconductor.

10. The multilayer thermoelectric transducer according to claim 1, wherein the p-type layer further contains a material used as an n-type semiconductor.

11. The multilayer thermoelectric transducer according to claim 10, wherein the material used as the n-type semiconductor contained in the p-type layer contains Zr.

12. The multilayer thermoelectric transducer according to claim 9, wherein the material used as the n-type semiconductor contained in the p-type layer contains Zr.

13. The multilayer thermoelectric transducer according to claim 8, wherein the material used as the n-type semiconductor contained in the p-type layer contains Zr.

14. The multilayer thermoelectric transducer according to claim 7, wherein the material used as the n-type semiconductor contained in the p-type layer contains Zr.

15. The multilayer thermoelectric transducer according to claim 1, wherein the p-type layer further contains the n-type semiconductor material having the same composition as the n-type semiconductor material contained in the n-type layer.

16. The multilayer thermoelectric transducer according to claim 2, wherein the p-type layer further contains the n-type semiconductor material having the same composition as the n-type semiconductor material contained in the n-type layer.
